(19) United States
(12) Patent Application Publication
(10) Pub. No.: US 2023/0377918 A1
(43) Pub. Date: Nov. 23, 2023

(54) FAN-OUT PACKAGE STRUCTURE AND FAN-OUT PACKAGING METHOD

(71) Applicant: Forehope Electronic (Ningbo) Co., Ltd., Ningbo (CN)

(72) Inventor: Yuan GAO, Ningbo City (CN)

(21) Appl. No.: 18/195,244

(22) Filed: May 9, 2023

(30) Foreign Application Priority Data
May 19, 2022 (CN) 2022105411391

(51) Int. Cl. H01L 21/67; H01L 21/48; H01L 23/31; H01L 23/498

(52) U.S. Cl. CPC H01L 21/6723; H01L 21/4853; H01L 23/3128; H01L 23/49816; H01L 23/49838

(57) ABSTRACT

Provided are fan-out package structure and fan-out packaging method. Structure includes packaging element, plastic package body, first dielectric layer, and second dielectric layer, packaging element has first pad and second pad, height of first pad is lower than that of second pad, plastic package body plastic-seals packaging element, and end surface of first pad is exposed from surface of plastic package body, one side of first pad away from packaging element has first wiring layer, and first wiring layer has first solder ball; first dielectric layer is provided on one side of first wiring layer away from packaging element, end surface of second pad is exposed from surface of first dielectric layer, one side of second pad away from packaging element has second wiring layer, and second wiring layer has second solder ball; and one side of second wiring layer away from first wiring layer has second dielectric layer.

### CROSS-REFERENCE TO RELATED APPLICATION

The present disclosure claims the priority to the Chinese patent application with the filing No. 2022105411391 filed on May 19, 2022 with the Chinese Patent Office, and entitled “Fan-out Package Structure and Fan-out Packaging Method”, the contents of which are incorporated herein by reference in entirety.

### TECHNICAL FIELD

The present disclosure relates to the technical field of semiconductors, specifically to a fan-out package structure and a fan-out packaging method.

### BACKGROUND ART

In the existing fan-out technologies, multiple redistribution layers generally need to be arranged, so as to connect circuits of a functional pad and a grounding pad on a chip to the outside, while to connect the grounding pad or the functional pad to the outside, multiple redistribution layers need to be connected to each other through conductive holes and conductive posts to realize fan-out extension of the pads of the chip. The larger the number of redistribution layers to be manufactured is, the more complicated the process of the required wiring layer is, and the larger the number of conductive holes is, thus increasing the cost. Besides, the conductive holes in the redistribution layers necessarily will increase parasitic effect and capacitive effect between circuit layers, thereby causing interference with signal transmission and poor heat dissipation effect of product.

### SUMMARY

Objectives of the present disclosure include, for example, providing a fan-out package structure and a fan-out packaging method, which, without the need of additionally providing conductive posts, is conducive to simplifying the process, reducing parasitic effect and capacitive effect, avoiding interference with signal transmission, and improving heat dissipation effect of the product.

The objectives of the present disclosure can be realized as follows.

The present disclosure provides a fan-out package structure, including a packaging element, a plastic package body, a first dielectric layer, and a second dielectric layer, the packaging element is provided thereon with a first pad and a second pad, height of the first pad is lower than that of the second pad, the plastic package body plastic-seals the packaging element, and an end surface of the first pad is exposed from a surface of the plastic package body, one side of the first pad away from the packaging element is provided with a first wiring layer, the first wiring layer is electrically connected to the first pad, and the first wiring layer is provided thereon with a first solder ball; and the first dielectric layer is provided on one side of the first wiring layer away from the packaging element, an end surface of the second pad is exposed from a surface of the first dielectric layer, one side of the second pad away from the packaging element is provided with a second wiring layer, and the second pad is electrically connected to the second wiring layer; the second wiring layer is provided thereon with a second solder ball; and one side of the second wiring layer away from the first wiring layer is provided with a second dielectric layer.

The present disclosure further provides a fan-out packaging method, including:
placing a packaging element on a carrier, and forming a first pad and a second pad on a side of the packaging element away from the carrier, wherein height of the second pad is higher than that of the first pad;
forming a plastic package body on a periphery of the packaging element, and exposing a surface of the first pad from a surface of the plastic package body;
fanning out the first wiring layer from the first pad; providing the first dielectric layer to cover the first wiring layer, and exposing a surface of the second pad from a surface of the first dielectric layer;
providing a first solder ball electrically connected to the first wiring layer;
fanning out the second wiring layer from the second pad, and providing a second dielectric layer to cover the second wiring layer; and
providing a second solder ball electrically connected to the second wiring layer.

### BRIEF DESCRIPTION OF DRAWINGS

In order to more clearly illustrate technical solutions of embodiments of the present disclosure, drawings which need to be used in the embodiments will be introduced briefly below, and it should be understood that the drawings below merely show embodiments of the present disclosure, therefore, they should not be considered as limitation to the scope, and those ordinarily skilled in the art still could obtain other relevant drawings according to these drawings, without using any creative efforts.

FIG. 1 is a first structural schematic diagram of a fan-out package structure provided in an embodiment of the present disclosure;

FIG. 2 is a second structural schematic diagram of the fan-out package structure provided in an embodiment of the present disclosure;

FIG. 3 is a top view of the fan-out package structure provided in an embodiment of the present disclosure;

FIG. 4 is a third structural schematic diagram of the fan-out package structure provided in an embodiment of the present disclosure;

FIG. 5 is a fourth structural schematic diagram of the fan-out package structure provided in an embodiment of the present disclosure;

FIG. 6 is a fifth structural schematic diagram of the fan-out package structure provided in an embodiment of the present disclosure;

FIG. 7 is a schematic structural diagram of configuration of a fourth electroplating bath in the fan-out package structure provided in an embodiment of the present disclosure;

FIG. 8 is a first schematic diagram of a manufacturing process of a fan-out packaging method provided in an embodiment of the present disclosure;

FIG. 9 is a second schematic diagram of the manufacturing process of the fan-out packaging method provided in an embodiment of the present disclosure;

FIG. 10 is a third schematic diagram of the manufacturing process of the fan-out packaging method provided in an embodiment of the present disclosure; and

FIG. 11 is a fourth schematic diagram of the manufacturing process of the fan-out packaging method provided in an embodiment of the present disclosure.

Reference signs: 100—fan-out package structure; 101—back film; 110—chip; 111—first chip; 113—second chip; 115—flip chip; 120—plastic package body; 130—first pad; 131—first wiring layer; 133—first dielectric layer; 135—first electroplating bath; 137—first bump; 138—third bump; 139—first solder ball; 140—second pad; 141—second wiring layer; 143—second dielectric layer; 145—second electroplating bath; 147—second bump; 149—second solder ball; 151—first buffer layer; 153—third pad; 155—second buffer layer; 161—fourth electroplating bath; 163—metal block.

### DETAILED DESCRIPTION OF EMBODIMENTS

In order to make the objectives, technical solutions, and advantages of the embodiments of the present disclosure clearer, the technical solutions in the embodiments of the present disclosure will be described below clearly and completely in conjunction with the drawings in the embodiments of the present disclosure, and apparently, only some but not all embodiments of the present disclosure are described. Generally, components in the embodiments of the present disclosure, as described and shown in the drawings herein, may be arranged and designed in various different configurations.

Therefore, the detailed description below of the embodiments of the present disclosure provided in the drawings is not intended to limit the scope of protection of the present disclosure, but merely illustrates chosen embodiments of the present disclosure. On the basis of the embodiments of the present disclosure, all of other embodiments, obtained by a person ordinarily skilled in the art without using any creative efforts, should fall within the scope of protection of the present disclosure.

It should be noted that similar reference signs and letters represent similar items in the following drawings, therefore, once a certain item is defined in one drawing, it is not needed to be defined or explained in subsequent drawings.

In the description of the present disclosure, it should be noted that orientation or positional relationships indicated by terms such as “upper”, “lower”, “inner” and “outer”, if appear, are based on orientation or positional relationships as shown in the drawings, or orientation or positional relationships of a product of the present disclosure when being conventionally placed in use, merely for facilitating describing the present disclosure and simplifying the description, rather than indicating or implying that related devices or elements have to be in the specific orientation or configured and operated in a specific orientation, therefore, they should not be construed as limitation to the present disclosure.

Besides, terms such as “first” and “second” are merely for distinguishing the description, but should not be construed as indicating or implying importance in the relativity.

It should be noted that the features in the embodiments of the present disclosure may be combined with each other without conflict.

A fan-out package structure provided in the present disclosure includes a packaging element, a plastic package body, a first dielectric layer, and a second dielectric layer, the packaging element is provided thereon with a first pad and a second pad, height of the first pad is lower than that of the second pad, the plastic package body plastic-seals the packaging element, and an end surface of the first pad is exposed from a surface of the plastic package body, one side of the first pad away from the packaging element is provided with a first wiring layer, the first wiring layer is electrically connected to the first pad, and the first wiring layer is provided thereon with a first solder ball; and the first dielectric layer is provided on one side of the first wiring layer away from the packaging element, an end surface of the second pad is exposed from a surface of the first dielectric layer, one side of the second pad away from the packaging element is provided with a second wiring layer, and the second pad is electrically connected to the second wiring layer; the second wiring layer is provided thereon with a second solder ball; and one side of the second wiring layer away from the first wiring layer is provided with a second dielectric layer.

In some embodiments, the first dielectric layer is provided thereon with a first electroplating bath, the first electroplating bath is provided therein with a first bump, the first bump is electrically connected to the first wiring layer, and the first solder ball is provided on the first bump.

In some embodiments, the second dielectric layer is provided thereon with a second electroplating bath, the second electroplating bath is provided therein with a second bump, the second bump is electrically connected to the second wiring layer, and the second solder ball is provided on the second bump.

In some embodiments, diameter of the first solder ball is larger than that of the second solder ball.

In some embodiments, height of the first solder ball is equal to sum of height of the second solder ball and height of the second dielectric layer.

In some embodiments, the second pad is a grounding pad or a shielding pad.

In some embodiments, the first solder ball is partially embedded in the second dielectric layer.

In some embodiments, the second dielectric layer is provided with a third electroplating bath, the third electroplating bath is provided therein with a third bump, the third bump is connected to the first wiring layer, and the first solder ball is connected to the third bump.

In some embodiments, the first solder ball and the second solder ball are of an equal dimension.

In some embodiments, the first wiring layer and the second wiring layer are electrically connected through the first solder ball.

In some embodiments, a first buffer layer is further included, the first buffer layer is provided between the first pad and the second pad adjacent to each other or between two adjacent second pads, and a coefficient of thermal expansion of the first buffer layer is smaller than that of the plastic package body.

In some embodiments, if the first buffer layer is provided between the first pad and the second pad adjacent to each other, the first buffer layer is made of an insulation material; and if the first buffer layer is provided between two adjacent second pads, the first buffer layer is made of an insulation material or a conductive material.

In some embodiments, a flip chip is further included, and the flip chip is provided on the first wiring layer and electrically connected to the first wiring layer.

In some embodiments, the first wiring layer is provided thereon with a third pad, and the flip chip is provided on the third pad.

In some embodiments, the packaging element includes a first chip and a second chip which are arranged at intervals, the first chip and the second chip are arranged at intervals, the flip chip is connected to the second wiring layer through the first chip and/or the second chip, and the second wiring layer is configured as the grounding circuit.

In some embodiments, a second buffer layer is further included, the second buffer layer is provided on a side of the first wiring layer away from the flip chip, the second buffer layer is provided between the first chip and the second chip, and a coefficient of thermal expansion of the second buffer layer is smaller than that of the plastic package body.

In some embodiments, the first dielectric layer is provided thereon with a fourth electroplating bath, the fourth electroplating bath is provided around the second pad, the fourth electroplating bath is provided therein with a metal block, the metal block is directly connected to the second pad, and the metal block is configured to lead out the second wiring layer.

In some embodiments, a distance between the first pad and the second pad is W1, a distance between the two adjacent second pads is W1, and width of a bath opening of the fourth electroplating bath is W2, wherein W2=W1/2; and width of a bath bottom of the fourth electroplating bath is W3, wherein W3=W2/2.

For the fan-out package structure provided in the present disclosure, the first pad and the second pad of different heights are provided on the packaging element, wherein the first wiring layer is fanned out from the surface of the relatively low first pad, the second wiring layer is fanned out from the surface of the relatively high second pad, and the first dielectric layer playing an insulating and protecting role is provided on the first wiring layer; the second wiring layer is provided thereon with the second dielectric layer covering the second wiring layer to play an insulating and protecting role. As the first pad and the second pad are of different heights, there is no need to additionally provide a conductive hole and a conductive post when manufacturing the second wiring layer, thus simplifying the process steps, meanwhile reducing the parasitic effect and the capacitive effect, avoiding interference with the signal transmission, and improving the heat dissipation effect of the product.

A fan-out packaging method provided in the present disclosure includes:
placing a packaging element on a carrier, and forming a first pad and a second pad on a side of the packaging element away from the carrier, wherein height of the second pad is higher than that of the first pad;
forming a plastic package body on a periphery of the packaging element, and exposing a surface of the first pad from a surface of the plastic package body;
fanning out the first wiring layer from the first pad; providing the first dielectric layer to cover the first wiring layer, and exposing a surface of the second pad from a surface of the first dielectric layer;
providing a first solder ball electrically connected to the first wiring layer;
fanning out the second wiring layer from the second pad, and providing a second dielectric layer to cover the second wiring layer; and
providing a second solder ball electrically connected to the second wiring layer.

In some embodiments, in the step of forming a first pad and a second pad on a side of the packaging element away from the carrier:
forming the first pad and the second pad by electroplating on the packaging element;
alternatively, forming encapsulation bodies on the packaging element, providing grooves on the encapsulation bodies, and filling metal posts in the grooves, so as to form the first pad and the second pad.

In some embodiments, in the step of providing a first solder ball electrically connected to the first wiring layer:
providing a first electroplating bath on the first dielectric layer, forming a first bump inside the first electroplating bath, the first bump being connected to the first wiring layer, and providing a first solder ball connected to the first bump; and in the step of providing a second solder ball electrically connected to the second wiring layer:

providing a second electroplating bath on the second dielectric layer, forming a second bump inside the second electroplating bath, the second bump being connected to the second wiring layer, and providing the second solder ball connected to the second bump, wherein diameter of the first solder ball is larger than that of the second solder ball.

In some embodiments, height of the first solder ball is equal to sum of height of the second solder ball and height of the second dielectric layer.

In some embodiments, the step of providing a first solder ball electrically connected to the first wiring layer includes:
providing a third electroplating bath on the second dielectric layer, the third electroplating bath penetrating through the second dielectric layer and the first dielectric layer; and forming a third bump in the third electroplating bath, the third bump being connected to the first wiring layer, and providing the first solder ball connected to the third bump.

In some embodiments, the step of fanning out the second wiring layer from the second pad includes:

providing a fourth electroplating bath on the first dielectric layer; providing a metal block in the fourth electroplating bath, the metal block being directly connected to the second pad, and leading out the second wiring layer from the metal block.

In some embodiments, the step of providing a fourth electroplating bath on the first dielectric layer includes:

forming the fourth electroplating bath through an etching process, wherein a distance between the first pad and the second pad is W1, a distance between two adjacent second pads is W1, and width of a bath opening of the fourth electroplating bath is W2, wherein W2=W1/2; and width of a bath bottom of the fourth electroplating bath is W3, wherein W3=W2/2.

In some embodiments, bath depth of the fourth electroplating bath is thickness of the first dielectric layer.

In some embodiments, the step of fanning out the second wiring layer from the second pad includes:
electrically connecting the second wiring layer to the first wiring layer through the first solder ball.

In some embodiments, the fan-out packaging method further includes providing a first buffer layer, the first buffer layer being provided between the first pad and the second pad adjacent to each other or between two adjacent second pads, wherein
if the first buffer layer is provided between the first pad and the second pad adjacent to each other, the first buffer layer is made of an insulation material; and if the first buffer layer is provided between two adjacent second pads, the first buffer layer is made of an insulation material or a conductive material; and
a coefficient of thermal expansion of the first buffer layer is smaller than that of the plastic package body.

In some embodiments, in the step of providing the first buffer layer:
providing the first buffer layer after the step of providing the first dielectric layer.

In some embodiments, after the step of fanning out the first wiring layer from the first pad, further including:
providing a flip chip on the first wiring layer.

In some embodiments, the packaging element includes a first chip and a second chip which are arranged at intervals, and the first chip and the second chip are arranged at intervals; and the step of providing a flip chip on the first wiring layer includes:
connecting the flip chip to the second wiring layer through the first chip and/or the second chip, and using the second wiring layer as a grounding circuit.

In some embodiments, the method further includes providing a second buffer layer, the second buffer layer is provided on a side of the first wiring layer away from the flip chip, the second buffer layer is provided between the first chip and the second chip, and a coefficient of thermal expansion of the second buffer layer is smaller than that of the plastic package body.

For the fan-out packaging method provided in the present disclosure, the first pad and the second pad of different heights are formed on the packaging element, wherein the first wiring layer and the second wiring layer are fanned out from the first pad and the second pad respectively, which can simplify the process, without the need of additionally providing the conductive holes or the conductive posts, meanwhile reduce the parasitic effect and the capacitive effect, avoid the interference with signal transmission, and improve the heat dissipation effect of the product.

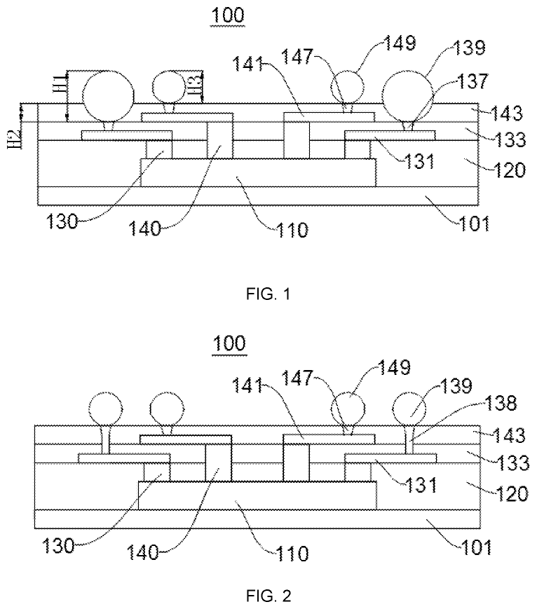

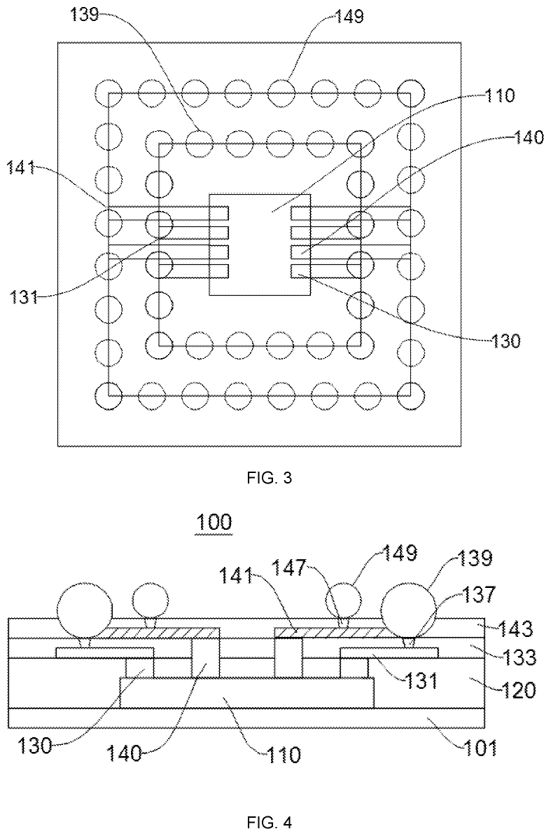

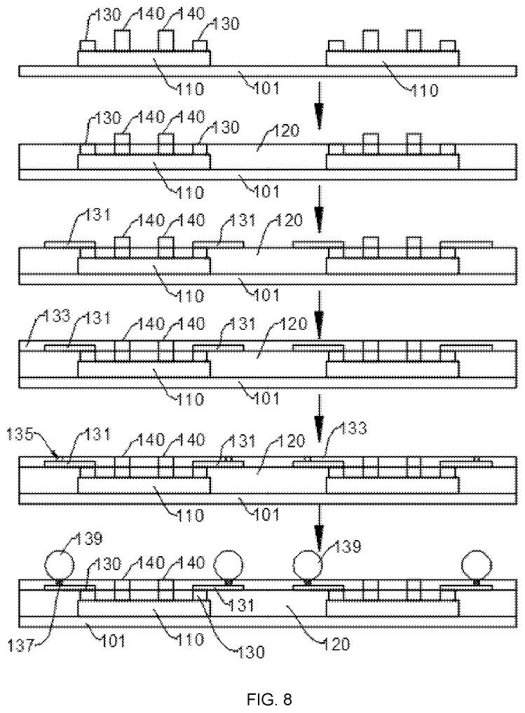

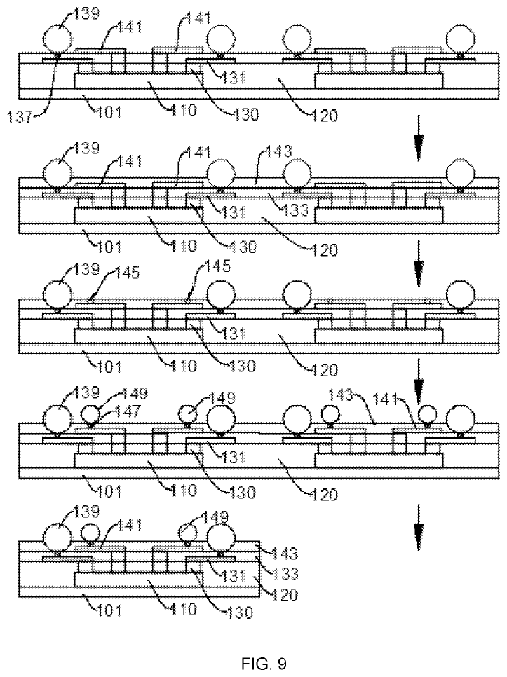

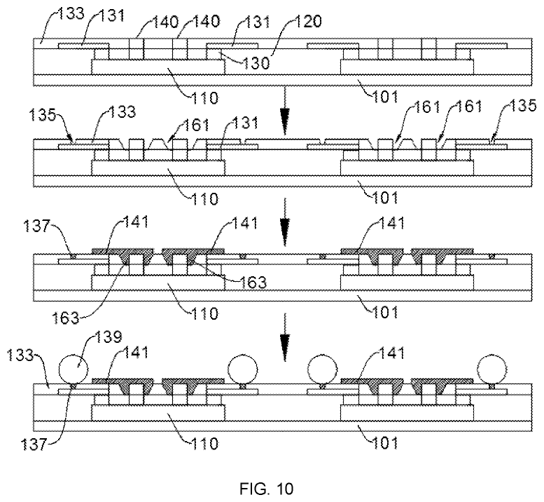

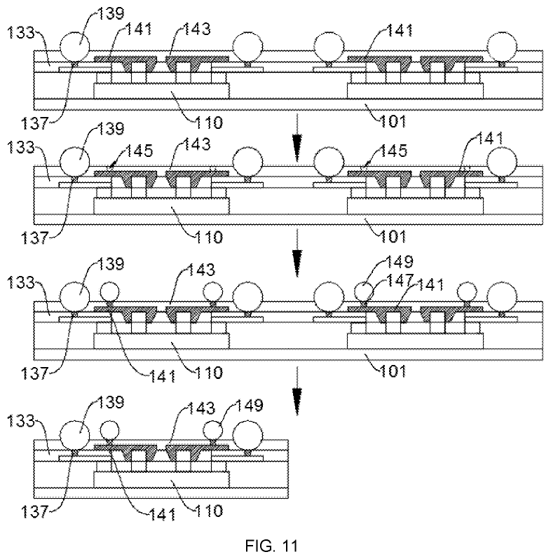

Referring to FIG. 1 to FIG. 3, and in conjunction with FIG. 8 to FIG. 11, the present embodiment provides a fan-out package structure 100, including a packaging element, a plastic package body 120, a first dielectric layer 133, and a second dielectric layer 143, wherein the packaging element includes, but is not limited to, a chip 110 or other elements, the chip 110 is provided thereon with a first pad 130 and a second pad 140, height of the first pad 130 is lower than that of the second pad 140, the plastic package body 120 plastic-seals the chip 110, and an end surface of the first pad 130 is exposed from a surface of the plastic package body 120, one side of the first pad 130 away from the chip 110 is provided with a first wiring layer 131, the first wiring layer 131 is electrically connected to the first pad 130, and the first wiring layer 131 is provided thereon with a first solder ball 139; the first dielectric layer 133 is provided on one side of the first wiring layer 131 away from the chip 110, an end surface of the second pad 140 is exposed from a surface of the first dielectric layer 133, one side of the second pad 140 away from the chip 110 is provided with a second wiring layer 141, and the second pad 140 is electrically connected to the second wiring layer 141; the second wiring layer 141 is provided thereon with a second solder ball 149; and one side of the second wiring layer 141 away from the first wiring layer 131 is provided with a second dielectric layer 143. The first solder ball 139 and the second solder ball 149 are used for connecting to an external circuit board, etc. By setting the heights of the first pad 130 and the second pad 140 to be different, the number of wiring layers can be reduced, and additionally providing conductive holes, conductive posts, etc. is avoided, then the process is simpler, the parasitic effect and the capacitive effect can be reduced, the signal transmission is prevented from being interfered with, and the heat dissipation performance is improved.

In some embodiments, a back surface of the chip 110 is provided with a back film 101, to protect the chip 110, and mitigate stress warpage during packaging, and the back film 101 can be removed according to practical situations.

The first dielectric layer 133 is provided thereon with a first electroplating bath 135, the first electroplating bath 135 is provided therein with a first bump 137, the first bump 137 is electrically connected to the first wiring layer 131, and the first solder ball 139 is provided on the first bump 137, thus facilitating the arrangement of the first solder ball 139, and being conducive to improving stability and reliability of connection between the first solder ball 139 and the first wiring layer 131. Similarly, the second dielectric layer 143 is provided thereon with a second electroplating bath 145, the second electroplating bath 145 is provided therein with a second bump 147, the second bump 147 is electrically connected to the second wiring layer 141, and the second solder ball 149 is provided on the second bump 147. The first bump 137 and the second bump 147 may each form a metal conductive block by means of electroplating, so that the process is simple, quick and convenient.

In the present embodiment, the first pad 130 is a functional pad, and the second pad 140 is a grounding pad or a shielding pad; that is, the first wiring layer 131 is a functional circuit of the chip 110, the second wiring layer 141 is a grounding circuit of the chip 110, the second wiring layer 141 is provided in the above, and the first wiring layer 131 is arranged between the chip 110 and the second wiring layer 141, which has a better protective effect on the functional circuit, prevents the first wiring layer 131 from being affected by electromagnetic interference and static electricity, and facilitates simplifying the subsequent electromagnetic shielding process. In some embodiments, diameter of the first solder ball 139 is greater than that of the second solder ball 149. By designing different dimensions of the first solder ball 139 and the second solder ball 149, connection terminals of the grounding circuit and connection terminals of the functional circuit can be visually distinguished, which is intuitive and clear, with clear circuits, and is convenient to locate a detection point or a fault point during inspection, maintenance, test or connection, thereby saving time and being not prone to errors. In the present embodiment, height H1 of the first solder ball 139 is equal to sum of height H3 of the second solder ball 149 and height H2 of the second dielectric layer 143, in this way, it is more convenient to implement the process, and the farthest protruding ends (sides away from the chip 110) of the first solder ball 139 and the second solder ball 149 are on the same plane, thereby facilitating installation and connection on the board.

It can be understood that the first solder ball 139 is used for functional connection, and the first solder ball 139 has a larger dimension. To use a big tin ball can achieve a better supporting effect, and when the first solder ball 139 is connected to an external circuit board, a contact area is larger, the connection is more reliable, and the binding performance is better. The second solder ball 149 adopts a small tin ball for connecting the grounding circuit and playing a protecting role, which can facilitate positioning maintenance and detection.

In some embodiments, the first solder ball 139 is partially embedded in the second dielectric layer 143, in this way, a better protective effect can be achieved on a joint between the first solder ball 139 and the first wiring layer 131, and appearance of crack or fracture is prevented after the first solder ball 139 is welded to the first bump 137, so that the electrical connection is more stable and reliable. Definitely, in other embodiments, the second solder ball 149 may also be partially embedded in the second dielectric layer 143, so as to ensure that the joint is more stable and reliable.

In some embodiments, the first solder ball 139 and the second solder ball 149 may also be designed with an equal dimension, which can simplify the manufacturing process of the solder balls. The first solder ball 139 and the second solder ball 149 are manufactured in the same batch, and when they are configured to be connected to the first wiring layer 131 and the second wiring layer 141 respectively, the first solder ball 139 and the second solder ball 149 do not need to be distinguished. In this embodiment, the second dielectric layer 143 is provided with a third electroplating bath, the third electroplating bath is provided therein with a third bump 138, the third bump 138 is connected to the first wiring layer 131, and the first solder ball 139 is connected to the third bump 138. In some embodiments, the third bump 138 adopts a metal conductive block, to achieve a reliable electrical connection between the first solder ball 139 and the first wiring layer 131. In the present embodiment, the third electroplating bath is provided on the second dielectric layer 143 by means of laser grooving, the third electroplating bath penetrates through the first dielectric layer 133, so as to expose the first wiring layer 131, and the third bump 138 is filled in the third electroplating bath, so that the first solder ball 139 is electrically connected to the first wiring layer 131 through the third bump 138.

Referring to FIG. 4, the first wiring layer 131 and the second wiring layer 141 are electrically connected through the first solder ball 139, to realize connection between the grounding circuit and the functional circuit, that is, the second wiring layer 141 is electrically connected to the first solder ball 139. This method does not require laser grooving and electroplating the conductive holes, which can simplify the process and reduce the number of wiring arranged. It should be noted that, for different application scenarios, whether the first wiring layer 131 and the second wiring layer 141 need to be electrically connected can be selected, and through the position design of the first solder ball 139, the first solder ball 139 can be selectively connected to or not connected to the second wiring layer 141. The present embodiment provides a plurality of fan-out structures according to different application scenarios and functional products, for example, a structure in FIG. 4, where the first solder ball 139 is connected to the second wiring layer 141, that is, the first wiring layer 131 is connected to the second wiring layer 141, or for example, a structure in FIG. 1, where the first solder ball 139 is not connected to the second wiring layer 141, that is, the first wiring layer 131 is not connected to the second wiring layer 141.

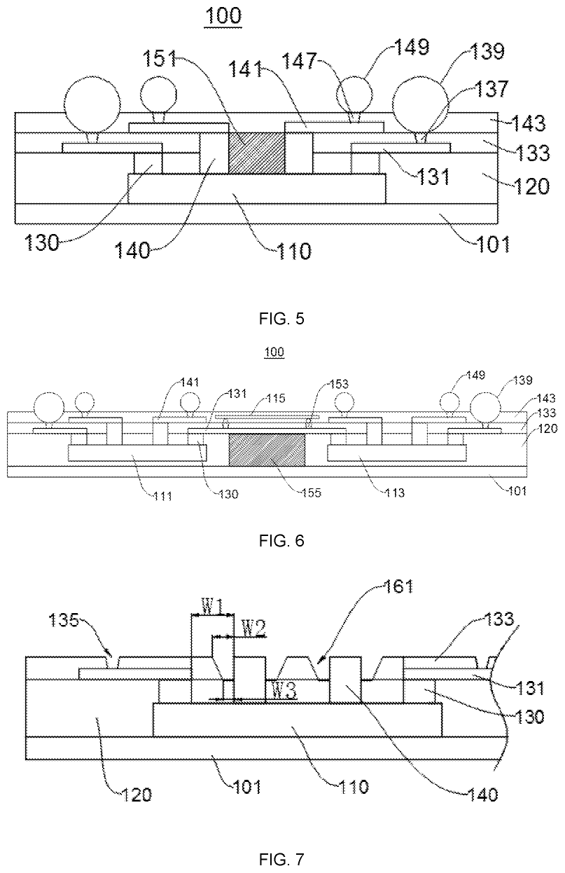

Referring to FIG. 5, in some embodiments, the fan-out package structure 100 further includes a first buffer layer 151, wherein the first buffer layer 151 is provided between adjacent first pad 130 and second pad 140 or between two adjacent second pads 140, and a coefficient of thermal expansion of the first buffer layer 151 is smaller than that of the plastic package body 120. In some embodiments, the first pad 130 and the second pad 140 are arranged at equal intervals on the chip 110. It can be understood that if the first buffer layer 151 is provided between the adjacent first pad 130 and second pad 140, the first buffer layer 151 is made of an insulation material; and if the first buffer layer 151 is provided between two adjacent second pads 140, the first buffer layer 151 is made of an insulation material or a conductive material. In the present embodiment, the first buffer layer 151 is provided between two adjacent second pads 140, the first buffer layer 151 is made of a conductive material, the two second pads 140 are electrically connected, and the second wiring layers 141 led out from the two second pads 140 are connected. The first buffer layer 151 can play a role of buffering, supporting, and dissipating heat, has a smaller coefficient of thermal expansion than that of the plastic package body 120, and can be deformed before the plastic package body 120, to absorb structural stress of the plastic package body 120, thus preventing deformation, and mitigating the phenomenon of stress warpage. The first buffer layer 151 may be made of a polymer composite material such as epoxy resin and polyimide, or the preceding polymer composite materials with addition of conductive particles including nano silver powder or nano copper therein.

With reference to FIG. 6, in some embodiments, the fan-out package structure 100 further includes a flip chip 115, wherein the flip chip 115 is provided on the first wiring layer 131 and electrically connected to the first wiring layer 131. In some embodiments, the first wiring layer 131 is provided thereon with a third pad 153, and the flip chip 115 is provided on the third pad 153. By providing the flip chip 115 on the first wiring layer 131, the degree of integration of the product can be improved. In the present embodiment, the chip 110 includes a first chip 111 and a second chip 113 which are arranged at intervals, the first chip 111 and the second chip 113 are arranged at intervals, the flip chip 115 is connected to the second wiring layer 141 through the first chip 111 and/or the second chip 113, and the second wiring layer 141 is configured as the grounding circuit. It can be understood that, the flip chip 115 is indirectly connected to the second wiring layer 141, and the second wiring layer 141 is configured as the grounding wiring. Therefore, no grounding wiring needs to be additionally arranged, the number of wiring layers is reduced, the manufacturing process is simplified, and the manufacturing efficiency is improved. It should be noted that, generally, a wiring layer must be covered by a dielectric layer as a protective layer, and signal attenuation of a high-frequency transmission signal circuit mainly comes from attenuation caused by dielectric layer loss, while in the present embodiment, the number of wiring layers is reduced, that is, the dielectric layer is reduced, so that high-frequency transmission of signal can be improved, and the performance of the product is improved.

In some embodiments, a second buffer layer 155 is further included, wherein the second buffer layer 155 is provided on a side of the first wiring layer 131 away from the flip chip 115, the second buffer layer 155 is provided between the first chip 111 and the second chip 113, and a coefficient of thermal expansion of the second buffer layer 155 is smaller than that of the plastic package body 120. In the present embodiment, the second buffer layer 155 is provided below the flip chip 115, and plays a role of supporting, buffering, and dissipating heat, thereby improving the heat dissipation performance, being conducive to mitigating stress warpage, and preventing deformation. Therefore, the precision of the first wiring layer 131 and the precision of the third pad 153 above can be effectively improved, and the mounting precision of the flip chip 115 can be improved.

Referring to FIG. 7, in some embodiments, a fourth electroplating bath 161 is provided on the first dielectric layer 133, the fourth electroplating bath 161 is provided around the second pad 140 and is in communication with the second pad 140, the fourth electroplating bath 161 is provided therein with a metal block 163, the metal block 163 is directly connected to the second pad 140, and the metal block 163 is configured to lead out the second wiring layer 141. With such arrangement, the binding force between the second pad 140 and the second wiring layer 141 can be improved, and the electrical connection is more stable and reliable. In the present embodiment, the first pad 130 and the second pad 140 on the chip 110 are arranged at equal intervals, a distance between the first pad 130 and the second pad 140 is W1, a distance between two adjacent second pads 140 is W1, and a width of a bath opening of the fourth electroplating bath 161 is W2, wherein W2=W1/2, that is, the width of the bath opening is half of the distance between two adjacent pads on the chip 110; and a width of a bath bottom of the fourth electroplating bath 161 is W3, wherein W3=W2/2, that is, the width of the bath bottom is half of the width of the bath opening, and a section of the fourth electroplating bath 161 is in an inverted trapezoidal shape. With such configuration, electroplating a metal layer in the fourth electroplating bath 161 can make the metal layer cover a side wall of the second pad 140, and the second wiring layer 141 and the metal block 163 can be integrally formed, thus a binding force between the second wiring layer and the second pad 140 can be improved.

In some embodiments, depth of the fourth electroplating bath 161 is equal to thickness of the second dielectric layer 143, to ensure that the fourth electroplating bath 161 does not contact a welding spot on the surface of the chip 110 in an etching process, thereby avoiding an undercutting phenomenon at the bottom of the welding spot in the conventional etching process, and thus improving the binding force. In the present embodiment, by precisely controlling the dimension of the fourth electroplating bath 161, the risk of excessive etching around the second pad 140 can be avoided, and by precisely controlling the dimension of the fourth electroplating bath 161, a volume of the metal block 163 can be controlled, a wiring structure around the second pad 140 can be effectively optimized, and the capacitive effect of the circuit layer is reduced, and current and voltage are balanced.

Referring to FIG. 8 to FIG. 11, and in combination with FIG. 1 to FIG. 7 for some structures, the fan-out packaging method provided in the present embodiment is mainly used for manufacturing various fan-out package structures 100 in the first embodiment, and the method mainly includes the following steps.

Step S100: mounting a packaging element on a carrier or a substrate, wherein the packaging element includes, but is not limited to, a chip 110 or other elements. In the present embodiment, the chip 110 is taken as an example for description. A back surface of the chip 110 is in contact with the carrier, and a first pad 130 and a second pad 140 are formed on a side of the chip 110 away from the carrier, wherein height of the second pad 140 is higher than that of the first pad 130; in some embodiments, the first pad 130 is designed as a functional pad, and the second pad 140 is designed as a grounding pad. The carrier can mitigate the stress warpage phenomenon in a subsequent manufacturing process, and after the manufacturing process is completed, the carrier can be separated. The carrier can use materials such as glass, silicon oxide, and metal as the back film 101.

In the above, in the step of forming the first pad 130 and the second pad 140 on a side of the chip 110 away from the carrier: an electroplating manner may be used, such that the first pad 130 and the second pad 140 are formed by electroplating on the chip 110. Alternatively, the first pad 130 and the second pad 140 also can be formed by providing grooves and then filling the grooves. Encapsulation bodies are first formed on the chip 110, a bath is provided on each encapsulation body, and a metal post is filled in the bath, so as to form the first pad 130 and the second pad 140. The metal posts can be filled by electroplating or in other manners, which is not specifically limited herein.

Step S200: forming a plastic package body 120 on a periphery of the chip 110, and making a surface of the first pad 130 to be exposed from a surface of the plastic package body 120, and making the second pad 140 to be exposed from the surface of the plastic package body 120. It can be understood that thickness of the plastic package body 120 is roughly equal to height of the first pad 130. In some embodiments, the plastic package body 120 is formed through a spin-coating process, so that the first pad 130 is covered and an upper surface of the first pad 130 is exposed.

Step S300: fanning out the first wiring layer 131 from the first pad 130. A region where no wiring needs to be fabricated is covered by a mask layer (a pattern layer), and a patterned opening is formed through exposure and development, and a metal layer is electroplated again, and fanning out is performed on an upper surface of the first pad 130, to form the first wiring layer 131.

The first dielectric layer 133 is provided so as to cover the first wiring layer 131, and functions to protect the first wiring layer 131, and an upper surface of the second pad 140 is exposed from a surface of the first dielectric layer 133. It can be understood that the surface of the first dielectric layer 133 is approximately flush with an end surface of one side of the second pad 140 away from the chip 110. The first dielectric layer 133 may also be formed through a spin-coating process, and the first dielectric layer 133 may also be formed through a physical vapor deposition process (PVD) or a chemical vapor deposition process (CVD). The first dielectric layer 133 may be made of silicon nitride, silicon oxynitride, polyimide, benzocyclobutene, etc.

Step S400: providing a first solder ball 139 electrically connected to the first wiring layer 131. In some embodiments, a first electroplating bath 135 is provided on the first dielectric layer 133, a first bump 137 is formed inside the first electroplating bath 135, the first bump 137 is connected to the first wiring layer 131, a first solder ball 139 is provided, and the first solder ball 139 is connected to the first bump 137, so as to achieve the electrical connection between the first solder ball 139 and the first wiring layer 131. The first electroplating bath 135 can be formed through an etching process, for example, by micro-etching with a plasma gas, the first electroplating bath 135 is formed on the surface of the first dielectric layer 133, the first wiring layer 131 is exposed, the metal layer is electroplated again, and a metal bump, i.e., the first bump 137, is formed on the first electroplating bath 135, where the first bump 137 can be made of a copper material. Again, a ball mounting process is performed on the first bump 137 by a steel-mesh printing method or a ball mounting method, that is, the first solder ball 139 is provided, where the first solder ball 139 is a tin ball, and may be made of a material such as SnAg and SnAgCu.

Step S500: fanning out the second wiring layer 141 from the second pad 140. A region where no wiring needs to be fabricated is covered by a mask layer (a pattern layer) again, and a patterned opening is formed through exposure and development, a metal layer is electroplated again, and fanning out is performed on an upper surface of the second pad 140, to form the second wiring layer 141, thus the first wiring layer 131 is separated from the second wiring layer 141.

The second dielectric layer 143 is provided so as to cover the second wiring layer 141, and functions to protect the second wiring layer 141. It can be understood that the first solder ball 139 is partially embedded in the second dielectric layer 143. The method of providing the second dielectric layer 143 is similar to the method of providing the first dielectric layer 133, and is not repeated herein.

Step S600: providing a second solder ball 149 electrically connected to the second wiring layer 141. In some embodiments, a second electroplating bath 145 is provided on the second dielectric layer 143, a second bump 147 is formed inside the second electroplating bath 145, the second bump 147 is connected to the second wiring layer 141, and the second solder ball 149 is provided to be connected to the second bump 147, so as to achieve the electrical connection between the second solder ball 149 and the second wiring layer 141. The method of providing the second solder ball 149 is similar to the method of providing the first solder ball 139, and is not repeated herein.

It should be noted that, in the conventional process, first, it is required to lead out a pad from one wiring layer, then a wiring layer below is connected to a wiring layer above by a conductive post, after that, a pad and a tin ball are fabricated on the wiring layer above. However, in the present embodiment, by forming the first pad 130 and the second pad 140 of different heights on the chip 110, the first wiring layer 131 is naturally separated from the second wiring layer 141, which can reduce the number of wiring layers and does not need to additionally add the conductive post, thereby reducing the parasitic effect and the capacitive effect on the wiring layers, and improving the signal transmission performance and heat dissipation performance of the product. Moreover, the configuration of the second pad 140 in the present embodiment can improve the binding force between the first dielectric layer 133 and the second dielectric layer 143, and prevent structural stratification or hidden cracking. The second pad 140 is higher, and is preferred to be designed as a grounding pad or a shielding pad, and the first wiring layer 131 is preferred to be designed as a functional circuit. In this way, the second wiring layer 141 is designed above the first wiring layer 131, so that a shielding circuit or a grounding circuit can covered above the first wiring layer 131, thereby protecting the first wiring layer 131, and preventing the first wiring layer 131 from being affected by electromagnetic interference and static electricity.

After the second solder ball 149 is manufactured, the carrier on the back surface of the chip 110 can be removed by irradiating ultraviolet light, to expose the back surface of the chip 110, thus improving the heat dissipation effect.

It should be noted that in some embodiments, diameter of the first solder ball 139 is larger than that of the second solder ball 149. That is, the first solder ball 139 is a large tin ball, the second solder ball 149 is a small tin ball, the first wiring layer 131 can be designed as a functional circuit, and the second wiring layer 141 can be designed as a grounding circuit. The configuration of large and small tin balls can make the functional circuit and the grounding circuit to be intuitively distinguished, facilitating the positioning during overhaul and maintenance. Moreover, as the first solder ball 139 is a large tin ball, the first solder ball 139 has a larger contact area with a circuit board when being mounted on board, with a better binding force. By providing the grounding circuit above, the first wiring layer 131 can be better protected, and meanwhile the first wiring layer 131 can be prevented from being affected by electromagnetic interference and static electricity. In some embodiments, height of the first solder ball 139 is equal to sum of height of the second solder ball 149 and height of the second dielectric layer 143, so that the farthest ends of the first solder ball 139 and the second solder ball 149 are located on the same plane, thereby facilitating installation on the board, such that the connection is more reliable. Definitely, in some other embodiments, the first wiring layer 131 and the second wiring layer 141 can also be designed as functional circuits respectively, and they are corresponding to different functional wirings of the product. The configuration of large and small tin balls plays a role in positioning and distinguishing, and makes the maintenance and test faster and more efficient.

It should be noted that, in other embodiments, the first solder ball 139 and the second solder ball 149 may also be of the same size, and the first solder ball 139 and the second solder ball 149 do not need to be distinguished during ball mounting, so that the process is simpler. If the first solder ball 139 and the second solder ball 149 are tin balls of the same size, the first wiring layer 131, the first dielectric layer 133, the second wiring layer 141, and the second dielectric layer 143 need to be provided in sequence, after the step of providing the second dielectric layer 143, a third electroplating bath is provided on the second dielectric layer 143, where the third electroplating bath penetrates through the second dielectric layer 143 and the first dielectric layer 133, a third bump 138 is formed in the third electroplating bath, where the third bump 138 is electrically connected to the first wiring layer 131, and the first solder ball 139 is provided on a surface of the second dielectric layer 143, so that the first solder ball 139 is electrically connected to the third bump 138, so as to realize electrical connection of the first solder ball 139 to the first wiring layer 131 through the third bump 138.

It is easy to understand that, in the manufacturing process, the second wiring layer 141 can be selectively connected to the first solder ball 139, or the second wiring layer 141 is connected to the third bump 138, so as to realize the electrical connection between the first wiring layer 131 and the second wiring layer 141, that is, the second wiring layer 141 is electrically connected to the first wiring layer 131 through the first solder ball 139 or the third bump 138. This is conducive to simplifying the process, reducing the number of wiring layers, and reducing the parasitic effect and the capacitive effect.

In some embodiments, the step of fanning out the second wiring layer 141 from the second pad 140 includes:

providing a fourth electroplating bath 161 on the first dielectric layer 133, wherein in some embodiments, the fourth electroplating bath 161 is formed through an etching process, wherein the distance between the first pad 130 and the second pad 140 is W1, the distance between two adjacent second pads 140 is W1, and width of a bath opening of the fourth electroplating bath 161 is W2, wherein W2=W1/2; and width of a bath bottom of the fourth electroplating bath 161 is W3, wherein W3=W2/2, and bath depth of the fourth electroplating bath 161 is thickness of the first dielectric layer 133. It is easy to understand that, after the fourth electroplating bath 161 is provided, an end of the second pad 140 away from the chip 110 is located in the fourth electroplating bath 161. A metal block 163 is provided in the fourth electroplating bath 161, the metal block 163 is directly connected to the second pad 140, and the second wiring layer 141 is led out from the metal block 163. In a practical manufacturing process, after the manufacturing step of the first dielectric layer 133 is completed, the first electroplating bath 135 and the fourth electroplating bath 161 can be simultaneously provided in one step, after that a metal layer is electroplated simultaneously in the first electroplating bath 135 and the fourth electroplating bath 161 to respectively form the first bump 137 and the metal block 163, wherein the first bump 137 is configured to connect the first solder ball 139, the metal block 163 is configured to connect the second wiring layer 141, and the metal forming the metal block 163 is directly attached to a side surface and an upper surface of the second pad 140. The metal block 163 and the second wiring layer 141 are integrally molded, which improves the binding force between the second pad 140 and the second wiring layer 141, and the electrical connection is more stable and reliable. By precisely controlling the dimension and position of the fourth electroplating bath 161, the risk of excessive etching around the second pad 140 can be avoided, a volume of the metal block 163 can be controlled, a wiring structure around the second pad 140 can be effectively optimized, the capacitive effect of the circuit layer is reduced and current and voltage are balanced.

After the second wiring layer 141 is provided, first, the first solder ball 139 is provided, and then the second dielectric layer 143 is provided, so that the second dielectric layer 143 partially covers the first solder ball 139, and appearance of crack or fracture is prevented after the first solder ball 139 is welded to the first bump 137, so that the electrical connection is more stable and reliable. After that, a second electroplating bath 145 is provided on the second dielectric layer 143 to form the second bump 147, and the second solder ball 149 is provided, wherein the second solder ball 149 is electrically connected to the second bump 147.

Step S700: cutting the manufactured package structure into a plurality of package units, wherein a whole board structure is first prepared in one step during the manufacturing, and then the whole board structure is cut, so that the manufacturing efficiency can be effectively improved.

In some embodiments, after step S300, i.e., after completing the manufacturing of the first dielectric layer 133, a first buffer layer 151 is provided. In some embodiments, the first buffer layer 151 can be formed by means of spin coating, the first buffer layer 151 is arranged between two adjacent second pads 140, and the first buffer layer 151 may be made of a conductive material, and is used for connecting the second wiring layers 141 on the two second pads 140, and meanwhile plays a role of buffering, supporting, and dissipating heat. The first buffer layer 151 may be made of a polymer composite material such as epoxy resin and polyimide with addition of conductive particles (such as nano silver powder or nano copper) therein, wherein such materials are characterized by a smaller coefficient of thermal expansion than that of the plastic package body 120, and can be deformed before the plastic package body 120, to absorb structural stress of the plastic package body 120, thus preventing deformation, and mitigating the phenomenon of stress warpage. Definitely, the first buffer layer 151 also may be made of an insulation material, the first buffer layer 151 may be provided between adjacent first pad 130 and second pad 140, or provided between two adjacent second pads 140. If the first buffer layer 151 is provided between adjacent first pad 130 and second pad 140, the first buffer layer 151 is made of an insulation material; and if the first buffer layer 151 is provided between two adjacent second pads 140, the first buffer layer 151 is made of an insulation material or a conductive material.

In some other embodiments, it is also feasible that first the first buffer layer 151 is provided on the chip 110, and then the plastic package body 120 and the first dielectric layer 133 are manufactured, which has better effect in mitigating the stress warpage.

In some embodiments, if a flip chip 115 needs to be provided, the process is that after the step of fanning out the first wiring layer 131 from the first pad 130, the flip chip 115 is provided on the first wiring layer 131. In the present embodiment, the chip 110 includes a first chip 111 and a second chip 113 provided at intervals, wherein the first chip 111 and the second chip 113 are provided at intervals, a third pad 153 is formed on the first wiring layer 131, including but not limited to forming the third pad 153 by directly electroplating, or after forming the first dielectric layer 133, providing a bath in the first dielectric layer and then electroplating and filling the bath to form the third pad 153, wherein the flip chip 115 is mounted to the third pad 153, and is electrically connected to the third pad 153. As another embodiment, the flip chip 115 is connected to the second wiring layer 141 through the first chip 111 and/or the second chip 113, and the second wiring layer 141 is configured as a grounding circuit. In this way, no grounding wiring of the flip chip 115 needs to be additionally provided, the number of wiring layers is reduced, the manufacturing process is simplified, and the manufacturing efficiency is improved. Meanwhile, the number of wiring layers is reduced, i.e., the dielectric layers are reduced, so that the high-frequency transmission of signal can be improved, the performance of the product is improved, the thickness of the product structure is effectively reduced, and the heat dissipation effect is better.

In some embodiments, the method further includes providing a second buffer layer 155, wherein the second buffer layer 155 is provided on a side of the first wiring layer 131 away from the flip chip 115, and the second buffer layer 155 is provided between the first chip 111 and the second chip 113, and the second buffer layer 155 has a smaller coefficient of thermal expansion than that of the plastic package body 120. In the present embodiment, the second buffer layer 155 is provided before the step of forming the plastic package body 120, that is, the second buffer layer 155 is first formed by spraying, then the plastic package body 120 is formed through a spin-coating process. By using the characteristic that the second buffer layer 155 is deformed before the plastic package body 120, the structural stress of the plastic package body 120 is absorbed, and the bending deformation of the package structure is reduced, such that the precision of the first wiring layer 131 and the precision of the third pad 153 above can be effectively improved, and the mounting precision of the flip chip 115 is improved. The second buffer layer 155 is made of an insulation material, and plays a role of supporting, buffering, absorbing stress, dissipating heat and the like.

In the present embodiment, contents in other parts not mentioned are similar to those described in the first embodiment, and are not repeated herein again.

It should be noted that, the present embodiment only lists that the first pad 130 and the second pad 140 of different heights are included, to form the first wiring layer 131 and the second wiring layer 141 respectively. In some embodiments, the number of wiring layers in a practical packaging process may be more than two, for example, three or four or more layers, therefore, pads of different heights can be flexibly provided according to the number of wiring layers practically required, for example, three pads of different heights may be provided correspondingly if three wiring layers are required, and four pads of different heights may be provided correspondingly if four wiring layers are required, and a plurality of pads of different heights may be provided correspondingly if multiple wiring layers are required, and the plurality of circuit layers may include, but are not limited to being designed as functional circuits and grounding circuits, and all may be functional circuits; if there is a grounding circuit, the grounding circuit can be arranged on an uppermost layer to better protect the functional circuit. Definitely, the grounding circuit may also be arranged in an intermediate layer or a lower layer according to practical situations, which is not specifically limited. The solder balls corresponding to each wiring layer may be of different sizes, or all solder balls are designed the same, and the package structure and method thereof are similar to the package structure and method described above, which will not be repeated here.

To sum up, the fan-out package structure 100 and method provided in the embodiments of the present disclosure have beneficial effects in the following aspects.

For the fan-out package structure 100 provided in the embodiments of the present disclosure, the first pad 130 and the second pad 140 of different heights are provided on the chip 110, wherein the first wiring layer 131 is fanned out from the surface of the relatively low first pad 130, the second wiring layer 141 is fanned out from the surface of the relatively high second pad 140, and the first dielectric layer 133 playing an insulating and protecting role is provided on the first wiring layer 131; and the second wiring layer 141 is provided thereon with the second dielectric layer 143 covering the second wiring layer 141 to play an insulating and protecting role. As the first pad 130 and the second pad 140 are of different heights, there is no need to additionally provide a conductive hole and a conductive post when manufacturing the second wiring layer 141, thus simplifying the process steps, reducing the number of wiring layers, meanwhile reducing the parasitic effect and the capacitive effect, avoiding interference with the signal transmission, and improving the heat dissipation effect of the product. The first solder ball 139 and the second solder ball 149, which are tin balls of different dimensions, are easy to distinguish and position. By connecting the second wiring layer 141 to the first solder ball 139, the number of wiring layers can be effectively reduced; when providing the second wiring layer 141, by precisely controlling the dimension of the fourth electroplating bath 161, the risk of excessive etching around the second pad 140 can be avoided, and by precisely controlling the dimension of the fourth electroplating bath 161, the volume of the metal block 163 can be controlled, and the wiring structure around the second pad 140 can be effectively optimized, so that the capacitive effect of the circuit layer is reduced, current and voltage are balanced, and the performance of the product is improved. By providing the flip chip 115 on the first wiring layer 131, the level of integration of the product can be improved, and the flip chip 115 intelligently uses the second wiring layer 141 as the grounding wiring, thereby reducing the number of wiring layers. By providing the first buffer layer 151 and the second buffer layer 155, the heat dissipation effect of the product can be improved, and the product has high structural strength and good stability, such that stress is absorbed, warpage is relieved, and deformation is prevented.

For the fan-out packaging method provided in the embodiments of the present disclosure, the first pad 130 and the second pad 140 of different heights are formed on the chip 110, and the first wiring layer 131 and the second wiring layer 141 are led out from the first pad 130 and the second pad 140 respectively, which can simplify the process, without the need of additionally providing the conductive holes or the conductive posts, meanwhile reduce the parasitic effect and the capacitive effect, avoid the interference with signal transmission, and improve the heat dissipation effect of the product.

The above-mentioned are merely for specific embodiments of the present disclosure, but the scope of protection of the present disclosure is not limited thereto, and changes or substitutions that may be easily conceived by any skilled person familiar with the technical field within the technical scope disclosed in the present disclosure should fall within the scope of protection of the present disclosure. Therefore, the scope of protection of the present disclosure should be based on the scope of protection of the claims.

### INDUSTRIAL APPLICABILITY

For the fan-out package structure and the fan-out packaging method provided in the present disclosure, the first pad and the second pad of different heights are provided on the packaging element, and as the first pad and the second pad are of different heights, there is no need to additionally provide the conductive holes or the conductive posts when manufacturing the second wiring layer, which simplifies the process steps, and meanwhile reduces the parasitic effect and the capacitive effect, avoids the interference with signal transmission, and improve the heat dissipation effect of the product.

What is claimed is:

1. A fan-out package structure, wherein the fan-out package structure comprises a packaging element, a plastic package body, a first dielectric layer, and a second dielectric layer, the packaging element is provided thereon with a first pad and a second pad, wherein a height of the first pad is lower than that of the second pad, the plastic package body plastic-seals the packaging element, and an end surface of the first pad is exposed from a surface of the plastic package body, one side of the first pad away from the packaging element is provided with a first wiring layer, the first wiring layer is electrically connected to the first pad, and the first wiring layer is provided thereon with a first solder ball; and
the first dielectric layer is provided on one side of the first wiring layer away from the packaging element, an end surface of the second pad is exposed from a surface of the first dielectric layer, one side of the second pad away from the packaging element is provided with a second wiring layer, and the second pad is electrically connected to the second wiring layer; the second wiring layer is provided thereon with a second solder ball; and one side of the second wiring layer away from the first wiring layer is provided with the second dielectric layer.

2. The fan-out package structure according to claim 1, wherein the first dielectric layer is provided thereon with a first electroplating bath, the first electroplating bath is provided therein with a first bump, the first bump is electrically connected to the first wiring layer, and the first solder ball is provided on the first bump.

3. The fan-out package structure according to claim 1, wherein the second dielectric layer is provided thereon with a second electroplating bath, the second electroplating bath is provided therein with a second bump, the second bump is electrically connected to the second wiring layer, and the second solder ball is provided on the second bump.

4. The fan-out package structure according to claim 1, wherein a diameter of the first solder ball is larger than that of the second solder ball.

5. The fan-out package structure according to claim 1, wherein the first solder ball is partially embedded in the second dielectric layer.

6. The fan-out package structure according to claim 1, wherein the second dielectric layer is provided with a third electroplating bath, the third electroplating bath is provided therein with a third bump, the third bump is connected to the first wiring layer, and the first solder ball is connected to the third bump.

7. The fan-out package structure according to claim 1, further comprising a first buffer layer, wherein the first buffer layer is provided between the first pad and the second pad adjacent to each other or between two adjacent second pads, and a coefficient of thermal expansion of the first buffer layer is smaller than that of the plastic package body.

8. The fan-out package structure according to claim 7, wherein:
if the first buffer layer is provided between the first pad and the second pad adjacent to each other, the first buffer layer is made of an insulation material; and
if the first buffer layer is provided between the two adjacent second pads, the first buffer layer is made of an insulation material or a conductive material.

9. The fan-out package structure according to claim 1, further comprising a flip chip, wherein the flip chip is provided on the first wiring layer and electrically connected to the first wiring layer.

10. The fan-out package structure according to claim 9, wherein the first wiring layer is provided thereon with a third pad, and the flip chip is provided on the third pad.

11. The fan-out package structure according to claim 9, wherein the packaging element comprises a first chip and a second chip which are arranged at intervals, the first chip and the second chip are arranged at intervals, the flip chip is connected to the second wiring layer through the first chip and/or the second chip, and the second wiring layer is configured as a grounding circuit.

12. The fan-out package structure according to claim 1, wherein the first dielectric layer is provided thereon with a fourth electroplating bath, the fourth electroplating bath is provided around the second pad, the fourth electroplating bath is provided therein with a metal block, the metal block is directly connected to the second pad, and the metal block is configured to lead out the second wiring layer.

13. A fan-out packaging method, comprising steps of placing a packaging element on a carrier, and forming a first pad and a second pad on a side of the packaging element away from the carrier, wherein a height of the second pad is higher than that of the first pad;
forming a plastic package body on a periphery of the packaging element, and exposing a surface of the first pad from a surface of the plastic package body;
fanning out a first wiring layer from the first pad; providing a first dielectric layer to cover the first wiring layer, and exposing a surface of the second pad from a surface of the first dielectric layer;
providing a first solder ball electrically connected to the first wiring layer;
fanning out a second wiring layer from the second pad, and providing a second dielectric layer to cover the second wiring layer; and
providing a second solder ball electrically connected to the second wiring layer.

14. The fan-out packaging method according to claim 13, in the step of forming a first pad and a second pad on a side of the packaging element away from the carrier:
forming the first pad and the second pad by electroplating on the packaging element; and
alternatively, forming encapsulation bodies on the packaging element, providing grooves on the encapsulation bodies, and filling metal posts in the grooves, so as to form the first pad and the second pad.

15. The fan-out packaging method according to claim 13, wherein in the step of providing a first solder ball electrically connected to the first wiring layer:
providing a first electroplating bath on the first dielectric layer, forming a first bump inside the first electroplating bath, the first bump being connected to the first wiring layer, and providing the first solder ball connected to the first bump; and in the step of providing a second solder ball electrically connected to the second wiring layer:
providing a second electroplating bath on the second dielectric layer, forming a second bump inside the second electroplating bath, the second bump being connected to the second wiring layer, and providing the second solder ball connected to the second bump, wherein:
a diameter of the first solder ball is larger than that of the second solder ball.

16. The fan-out packaging method according to claim 15, wherein the step of providing a first solder ball electrically connected to the first wiring layer comprises:
providing a third electroplating bath on the second dielectric layer, the third electroplating bath penetrating through the second dielectric layer and the first dielectric layer; and
forming a third bump in the third electroplating bath, the third bump being connected to the first wiring layer, and providing the first solder ball connected to the third bump.

17. The fan-out packaging method according to claim 13, wherein the step of fanning out a second wiring layer from the second pad comprises:
providing a fourth electroplating bath on the first dielectric layer; and
providing a metal block in the fourth electroplating bath, the metal block being directly connected to the second pad, and leading out the second wiring layer from the metal block.

18. The fan-out packaging method according to claim 17, wherein the step of providing a fourth electroplating bath on the first dielectric layer comprises:
forming the fourth electroplating bath through an etching process, wherein a distance between the first pad and the second pad is W1, a distance between two adjacent second pads is W1, and a width of a bath opening of the fourth electroplating bath is W2, wherein W2=W1/2; and a width of a bath bottom of the fourth electroplating bath is W3, wherein W3=W2/2.

19. The fan-out packaging method according to claim 13, wherein the step of fanning out a second wiring layer from the second pad comprises:
electrically connecting the second wiring layer to the first wiring layer through the first solder ball.

20. The fan-out packaging method according to claim 13, further comprising providing a first buffer layer, the first buffer layer being provided between the first pad and the second pad adjacent to each other or between two adjacent second pads, wherein:
if the first buffer layer is provided between the first pad and the second pad adjacent to each other, the first buffer layer is made of an insulation material; and if the first buffer layer is provided between the two adjacent second pads, the first buffer layer is made of an insulation material or a conductive material; and
a coefficient of thermal expansion of the first buffer layer is smaller than that of the plastic package body.
